(19) United States
(12) Patent Application Publication
(10) Pub. No.: US 2007/0256298 A1
(43) Pub. Date: Nov. 8, 2007

(54) Boring device for boring via holes for connecting contact regions of multilayer printed circuit boards

(76) Inventor: Alfred Reinhold, Wunstorf (DE)

Correspondence Address: SHLESINGER, ARKWRIGHT & GARVEY LLP, 1420 KING STREET, SUITE 600, ALEXANDRIA, VA, 22314, US

(21) Appl. No.: 11/783,102

(22) Filed: Apr. 5, 2007

Related U.S. Application Data
(63) Continuation of application No. PCT/EP05/10823, filed on Oct. 7, 2005.

(30) Foreign Application Priority Data
Oct. 8, 2004 (DE) 10 2004 049 439.8

(51) Int. Cl. H05K 3/46; B23B 39/16

(52) U.S. Cl. 29/852; 408/50; 408/48

(57) ABSTRACT

Boring device for boring via holes for connecting contact regions of a first layer of a multilayer printed circuit board to contact regions of a second layer of the circuit board includes boring device for boring the via holes and control device for generating control signals for controlling boring device in accordance with via holes to be bored. A device is provided for determining a layer-to-layer misalignment between the first and second layers of the circuit board. Device is connected to control device for feeding a signal representing determined layer-to-layer misalignment to control device, which generates control signals as a function of determined layer-to-layer misalignment so that boring device bores via holes as a function of determined layer-to-layer misalignment. Boring device includes at least one laser for forming the via holes.

### CROSS-REFERENCE TO RELATED APPLICATIONS

This application is a continuation of application no. PCT/EP2005/010823, filed Oct. 7, 2005, which claims the priority of German application no. 10 2004 049 439.8, filed Oct. 8 2004, and each of which is incorporated herein by reference.

### FIELD OF THE INVENTION

The invention relates to a boring device for boring via holes for connecting contact regions of at least a first layer of a multilayer printed circuit board to contact regions of at least a second layer of the multilayer printed circuit board.

### BACKGROUND OF THE INVENTION

In the course of increasing miniaturization of electronic assemblies, it is necessary to provide a larger and larger number of components and conducting paths, respectively, on a given region, a printed circuit board for example. For this reason, it is known to design printed circuit boards as so-called multiple layer or multilayer printed circuit boards in which the printed circuit board includes a number of single printed circuit boards provided layer-like one over the other, so that components or conducting paths can be provided on the front and rear of the single printed circuit boards and, because of the layer-like construction, thereby also be provided between the single printed circuit boards succeeding each other in the layering. In this way it is possible in particular to realize printed circuit boards having a particularly high number of conducting paths which cannot be provided on a single printed circuit board. The single printed circuit boards, whose layering forms a multilayer printed circuit board, are attached to one another, by pressing or gluing for example.

To achieve transmission of electrical signals between, for example, a first layer and a second layer of the multilayer printed circuit board, it is necessary to connect the conducting paths of the layers to one another in an electrically conductive manner. To this end, the layers include contact regions, which are also called pads. The contact regions can, for example, be provided lying one above the other on the layers perpendicular to the plane of the multilayer printed circuit board. Via holes are bored to connect the contact regions in an electrically conductive manner, whereby the via holes connect the contact regions to one another mechanically, so that the electrically conductive connection can thereby be produced, for example, by making the inside walls of the via holes electrically conductive with solder or another electrically conductive material.

The via holes must be configured in such a manner that an electrically conducting contact between the contact regions becomes possible in the desired manner. This is possible without additional requirements if the contact regions are provided exactly one above the other perpendicular to the plane of the multilayer printed circuit board. However, it is necessary to take into consideration that a high pressure per unit area is used in conjunction with high temperatures when the layers of the multilayer printed circuit board are connected, by pressing for example. For this reason, a layer-to-layer misalignment between the layers can occur when they are connected. Such a layer-to-layer misalignment may be based on the fact that the single layers shrink or expand, and/or become displaced relative to one another parallel to the plane of the printed circuit board, and/or rotate relative to one another around an axis running perpendicular to the plane of the printed circuit board.

Given a layer-to-layer misalignment arising in this way, it will no longer be possible to form the electrically conductive connection between the contact regions of the layers through the via holes if the layer-to-layer misalignment lies outside of predefined tolerances. The printed circuit board must then be discarded as a reject.

To prevent the printed circuit boards in which the layer-to-layer misalignment lies outside of the predefined tolerances from requiring expensive further processing, such as when mounting components, it is known from DE 33 42 564 C2 to use an X-ray measuring device to determine the layer-to-layer misalignment.

A boring device of the type in question for boring via holes for connecting contact regions of at least a first layer of a multilayer printed circuit board to contact regions of at least a second layer of the multilayer printed circuit board is known. The known boring device includes boring device for boring the via holes and control device for generating control signals for controlling the boring device in accordance with the via holes to be bored. To fix the multilayer printed circuit board, which henceforth will be called printed circuit board for brevity, in the boring device, the printed circuit board includes locating holes which allow it to be placed on corresponding locating pins provided on a carrier, for example a boring machine table, of the boring device. The position of the locating holes thereby determines the position of the printed circuit board relative to the carrier.

In this connection, it is known to correct the position of the locating holes in the printed circuit board to compensate for a layer-to-layer misalignment that has occurred. To this end, the printed circuit board is brought into an X-ray measuring device so that any layer-to-layer misalignment of the layers of the printed circuit board can be determined, as known from DE 33 42 564 C2, for example. If a layer-to-layer misalignment is determined, then the position of the locating holes can be chosen in such a manner that the layer-to-layer misalignment is completely or partially compensated during the subsequent boring of the via holes, provided that the layer-to-layer misalignment lies within certain limits.

After determining the layer-to-layer misalignment and the boring of the locating holes in the printed circuit board, the printed circuit board is removed from the X-ray measuring device and brought into the boring device, where it is placed on the locating pins of the carrier. The boring device of the boring device then bores the desired via holes.

### OBJECTS AND SUMMARY OF THE INVENTION

The object of the invention is to provide a boring device for boring via holes for connecting contact regions of at least a first layer of a multilayer printed circuit board to contact regions of at least a second layer of the multilayer printed circuit board, as well as a method for boring via holes for connecting contact regions of at least a first layer of a multilayer printed circuit board to contact regions of at least a second layer of the multilayer printed circuit board, and in which device and process, respectively, the accuracy in boring the via holes is increased.

This object is achieved in regard to the boring device by the teaching set forth in the boring device and method for boring via holes for connecting contact regions of at least a first layer of a multilayer printed circuit board to contact regions of at least a second layer of the multilayer printed circuit board as described herein, including the figures and claims.

In accordance with the invention the determination of a layer-to-layer misalignment between the first layer and the second layer of the printed circuit board and the boring of the via holes are carried out in one and the same device. In this manner, the printed circuit board can remain attached to a carrier, such as a boring machine table of the boring device, both when determining the layer-to-layer misalignment and also when boring the via holes. In this way, it is reliably prevented that inaccuracies will result from mechanical fit tolerances in relation to the locating holes and locating pins when boring the via holes. As locating holes in the printed circuit board are basically not required according to the invention, and the printed circuit board can therefore be configured locating-hole-free, according to the invention the fit tolerances in relation to the locating holes will not influence accuracy during the boring of the via holes.

As both the determination of the layer-to-layer misalignment and the boring of the via holes are performed in the same device, namely the boring device, the printed circuit board is exposed to the same environmental conditions, such as temperature, in particular, during both the determining of the layer-to-layer misalignment and the boring of the via holes. This prevents a change in the geometry of the printed circuit board between the determination of a layer-to-layer misalignment and the boring of the via holes as a result of temperature differences, for example, in particular. In conventional devices, such a change in geometry can occur and cause inaccuracies in the boring of the via holes, particularly when the printed circuited board is removed from the X-ray measuring device after the layer-to-layer misalignment has been determined and brought into the boring device.

In this way according to the invention, the precision of the boring device according to the invention in boring the via holes is increased.

Further in accordance with the invention the boring device includes at least one laser for the forming of the via holes. In this manner, the accuracy of the boring of the via holes is increased even more. Still further, the speed at which the via holes are bored, as compared to mechanical boring machines, is markedly increased. A further advantage of using a laser for the boring of via holes is that, if need be, adjustment of the diameter of the via holes can be accomplished by an appropriate beam configuration and/or focusing of the laser beam. A time-consuming required changing of the drill bit of a mechanical boring machine can thus be dispensed with in accordance with the invention.

In addition, the device according to the invention is particularly easy and inexpensive to produce, because the structural cost is reduced substantially relative to the prior art. Whereas the prior art requires that essential and expensive components, such as in the form of the controller, a positioning table for positioning the printed circuit board and a housing, must be present in duplicate because of the fact that both a separate device for determining a layer-to-layer misalignment, such as in the form of an X-ray measuring device, and a separate boring device are required, in the boring device according to the invention, in which the device for determining a layer-to-layer misalignment is integrated into the boring device, these components are only required once. The boring device according to the invention is therefore not only substantially easier and less expensive to produce relative to the prior art, but also has a substantially reduced space requirement.

Integration of the device for determining a layer-to-layer misalignment into the boring device is understood to mean according to the invention that the boring device and the device for determining a layer-to-layer misalignment stand in such a spatial and/or functional relationship that the determination of the layer-to-layer misalignment and the boring of the via holes can occur without changing the location of the printed circuit board relative to a carrier that holds the printed circuit board. In particular, integration of the device for determining a layer-to-layer misalignment into the boring device is understood to mean according to the invention that the boring device and the device for determining the layer-to-layer misalignment are provided in direct spatial proximity to one another.

An advantageous development of the teaching according to the invention provides that the boring device and the device for determining a layer-to-layer misalignment fit onto a common base, especially into a common housing of the device. This embodiment is particularly compact and space-saving.

An extraordinarily advantageous development of the teaching according to the invention provides for a carrier for the printed circuit board, whereby during the boring of the via holes, the carrier holds the printed circuit board substantially free of positional change relative to the position of the printed circuit board during the determination of the layer-to-layer misalignment. In this embodiment, the printed circuit board occupies substantially the same position relative to the carrier both when determining the layer-to-layer misalignment and when boring the via holes. This reliably prevents misalignments of the via holes, which could result from a positional change of the printed circuit board relative to the carrier. In particular, it is possible for attaching device to fix the printed circuit board to the carrier during the determination of the layer-to-layer misalignment and during the boring of the via holes. The attaching of the printed circuit board on the carrier can be performed in any desired manner, such as by mechanical clamping or by fastening the printed circuit board to the carrier by adhesion using a suction device.

Carrier is understood to mean according to the invention that component which directly holds the printed circuit board, independently of the mechanical construction of the carrier. The carrier can for example be configured frame-like or as a table on which the printed circuit board lies flat.

A further development of the above-described embodiment provides that the carrier is configured in such a manner that the printed circuit board can be released for removal from the device only after the boring of the via holes. In this embodiment for example, the control device can be connected to attaching device, which attaches the printed circuit board to the carrier, in a control connection and, after the boring of the via holes, controls the attaching device in such a manner that the printed circuit board is released for removal.

Another development of the teaching according to the invention provides for positioning device for positioning the printed circuit board relative to the boring device and/or the device for determining the layer-to-layer misalignment. The control device can appropriately control the positioning device to bring the printed circuit board into a desired position relative to the boring device and also relative to the device for determining the layer-to-layer misalignment, so that the boring device and the device for determining the layer-to-layer misalignment can be provided stationary on a base of the device. The mechanical construction of the device is simplified in this way. The positioning device can be formed, for example, by a precision X-Y table that includes or forms the carrier for the printed circuit board.

A further development of the above-described embodiment provides that the positioning device can position the printed circuit board relative to the boring device and/or the device for determining the layer-to-layer misalignment at least in a plane parallel to the printed circuit board. But if desired according to the corresponding requirements, the printed circuit board can also be positioned relative to the boring device and/or the device for determining the layer-to-layer misalignment in a direction perpendicular to the plane of the printed circuit board.

The determination of the layer-to-layer misalignment can basically be accomplished by any desired suitable method. An advantageous further development of the teaching according to the invention provides that the device for determining the layer-to-layer misalignment determines the layer-to-layer misalignment by use of an imaging method.

A particularly advantageous further development of the teaching according to the invention provides that the device for determining the layer-to-layer misalignment includes at least one X-ray measuring device for measuring the layer-to-layer misalignment. These types of X-ray measuring devices make it possible to measure the printed circuit board and thereby measure the layer-to-layer misalignment with high accuracy.

An advantageous development of the above-described embodiment provides that the X-ray measuring device includes at least one microfocus X-ray tube. In this embodiment, the measurement of the layer-to-layer misalignment can be performed with particularly high accuracy. The X-ray measuring device can be configured in particular as an X-ray microscope.

Another development of the teaching according to the invention provides that the control device is programmed in such a manner that the control of the boring device is exercised only when the determined layer-to-layer misalignment of the layers relative to one another exceeds a predefined value. In this embodiment, the via holes are bored only when it has been determined on the basis of the determined layer-to-layer misalignment that the desired electrically conductive connection between the layers of the printed circuit boards can be accomplished by use of the via holes. If, on the other hand, it is determined that layer-to-layer misalignment lies below a predefined value, thereby making it impossible to achieve the desired electrically conductive contacting between the layers by way of via holes, then the printed circuit board can be rejected. This prevents a time-consuming and costly further processing of printed circuit boards that cannot be operable given a layer-to-layer misalignment lying outside the predefined tolerances and that consequently must be rejected.

In accordance with the respective requirements, the device for determining a layer-to-layer misalignment can determine the layer-to-layer misalignment on the basis of the contact regions of the layers of the printed circuit board and/or on the basis of markings provided in or on the layers of the printed circuit board.

In a method according to the invention, during the boring of the via holes a carrier holds the printed circuit board substantially free of positional changes relative to the position of the printed circuit board when the layer-to-layer misalignment is determined. In this way, it is possible to bore the via holes with high accuracy according to the invention without any impairment of this accuracy by positional changes of the printed circuit board relative to the carrier like the positional changes which arise in the prior art from removing the printed circuit board from a carrier of a device for determining a layer-to-layer misalignment and placing it on a carrier of a separate boring device. Essential in this connection is the freedom from positional changes of the printed circuit board relative to the carrier in a plane parallel to the printed circuit board.

Advantageous developments of the method according to the invention are set forth as described, claimed, and illustrated herein.

The invention will be explained in more detail below based on the enclosed, highly schematic drawing, which illustrates an exemplary embodiment of a boring device according to the invention for executing the method according to the invention. To this end, all of the features that are described or are illustrated in the drawing, per se or in any combination, form the subject matter of the invention independently of their combination in the claims or their dependencies, and independently of their wording and illustration in the description and drawing respectively.

Relative terms such as left, right, up, and down are for convenience only and are not intended to be limiting.

### BRIEF DESCRIPTION OF THE DRAWINGS

FIG. 1 shows in a perspective, highly schematic illustration, the layers of a multilayer printed circuit board prior to the connection of the layers to one another,

FIG. 2 is a vertical section through the printed circuit board of FIG. 1, whereby only two layers are depicted for reasons of illustration and whereby there is depicted a via hole, the inside wall of which is provided with an electrically conductive material,

FIG. 3 is a view from above of the printed circuit board of FIG. 2 in a first layer-to-layer misalignment of the layers of the printed circuit board to one another,

FIG. 4 shows in the same manner of illustration as in FIG. 3, the printed circuit board of FIG. 2 in a second layer-to-layer misalignment of the layers to one another,

FIG. 5 shows in the same manner of illustration as in FIG. 3, the printed circuit board of FIG. 2 in a third layer-to-layer misalignment of the layers to one another, and

FIG. 6 is a schematic side view of an exemplary embodiment of a boring device according to the invention for executing a method according to the invention, whereby components of the boring device are partially illustrated in a type of block diagram.

### DETAILED DESCRIPTION OF THE INVENTION

In the figure, the identical or corresponding components are designated with the same reference numerals.

FIG. 1 depicts, in a highly schematic form, a multilayer printed circuit board 2, which hereinafter will be called printed circuit board for brevity. The printed circuit board 2 includes a layer-like construction, whereby layers 4, 6, 8 of printed circuit board 2 are each formed by a single printed circuit board. The layers 4, 6, 8 of the printed circuit board 2 are attached to one another, such as by pressing or gluing. For purposes of illustration, the layers 4, 6, and 8 in FIG. 1 are not depicted in a state of connection to one another. For the sake of example only, the printed circuit board 2 as per FIG. 1 includes three layers. But the number of layers can be selected within large limits. The printed circuit board 2 can for example include only two layers or also of more than three layers.

In the production process of printed circuit board 2, the layers 4, 6, 8 include conducting paths, of which in FIG. 1 a conducting path of layer 4 is provided with the reference numeral 10, a conducting path of layer 6 with the reference numeral 12 and a conducting path of layer 8 with the reference numeral 14. The conducting paths 10, 12, 14 include an electrically conductive material and are connected to contact regions 16, 18 and 20, respectively, which are made of an electrically conductive material and, in this exemplary embodiment, are configured substantially circular in top view. The contact regions 16, 18, 20 can be connected to one another by a via hole, which in FIG. 1 is indicated by the reference numeral 22.

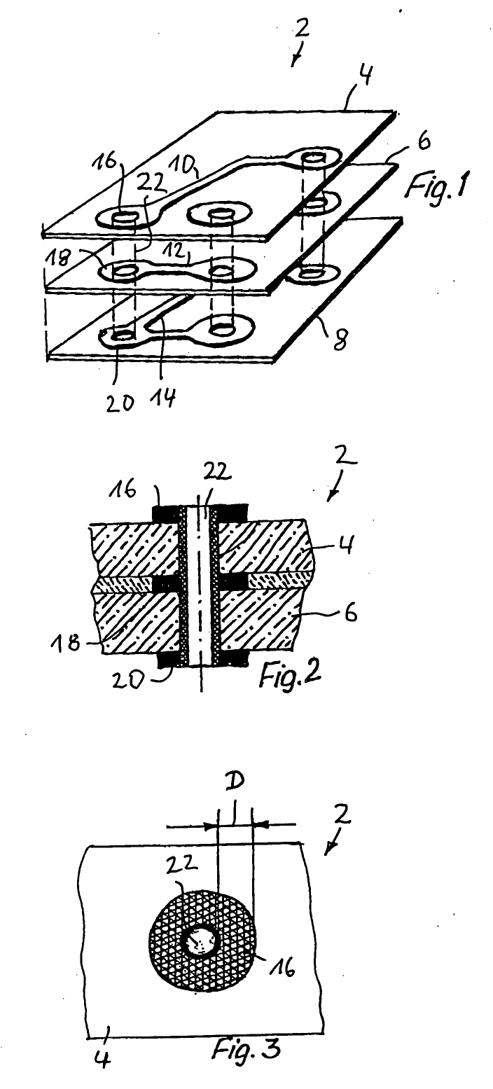

FIG. 2 depicts a vertical section through the printed circuit board 2 as per FIG. 1. To establish an electrically conductive connection between the contact regions 16, 18 and 20, the printed circuit board 2 is bored through in such a manner that the via hole 22 ideally runs coaxial to the contact regions 16, 18, 20. After the boring of the via hole 22, its inside wall is provided with an electrically conductive material, such as a solder, which produces an electrically conductive connection between the contact regions 16, 18 and 20 in the desired manner.

FIG. 3 shows a top view onto the printed circuit board 2 as per FIG. 2. When the layers 4, 6 and 8 are connected to one another, a layer-to-layer misalignment of the layers 4, 6 and 8 relative to one another can occur, for which reason the contact regions 16, 18 and 20 will then no longer lie exactly on top of one another in the desired manner perpendicular to the plane of the printed circuit board. A layer-to-layer misalignment can occur in particular from an expansion or shrinkage of at least one of the layers 4, 6 and 8, by a displacement of the layers 4, 6 and 8 relative to one another parallel to the plane of the printed circuit board, and/or by a rotation of the layers 4, 6, and 8 relative to one another around an axis running perpendicular to the plane of the printed circuit board and/or by a shearing action. FIG. 3 illustrates a printed circuit board 2 in which such a layer-to-layer misalignment has not occurred, so that the contact regions 16, 18 and 20 lie sequentially one above the other perpendicular to the plane of the printed circuit board. As evident from FIG. 3, the contact regions 16, 18 and 20 are substantially ring-shaped after the forming of the via hole 22, whereby in this case the via hole 22 runs coaxial to the contact regions 16, 18 and 20 in the desired manner. The ring-shaped contact regions 16, 18, 20 have a radial width D.

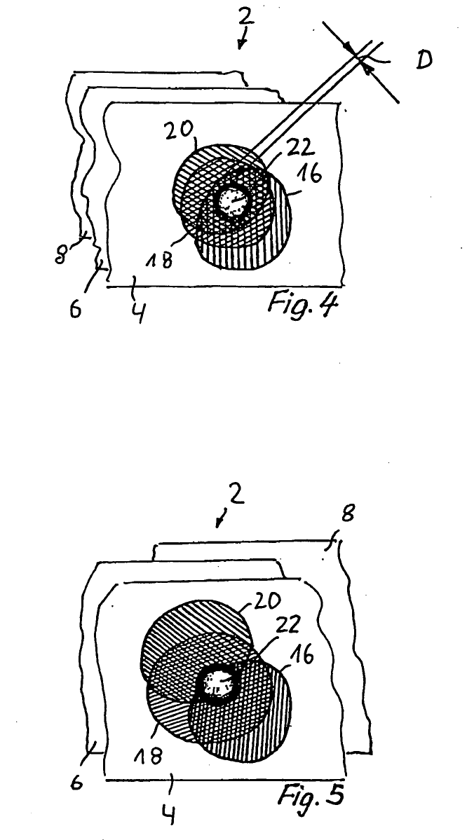

FIG. 4 illustrates a printed circuit board 2 in which a layer-to-layer misalignment has occurred, for which reason the via hole 22 is no longer coaxial to all contact regions 16, 18 and 20. Here the position of the via hole 22 is selected in such a manner that the remaining radial width D is as large as possible for all contact regions 16, 18 and 20. If the remaining radial width D of the contact regions 16, 18 and 20 falls below a predefined value, then the printed circuit board 2 cannot be further used and must be rejected.

FIG. 5 illustrates a printed circuit board 2 in which a layer-to-layer misalignment has occurred and is so large that it is not possible to ensure that all contact regions 16, 18 and 20 are ring-shaped with a predefined minimum radial width, even after optimization of the position of the via hole 22. Rather, in the printed circuit board illustrated in FIG. 5, the contact regions 16 and 18 are no longer ring-shaped after the boring of the via hole, but their external perimeter is interrupted in the radial direction. Such a printed circuit board can also not be further used and must be rejected.

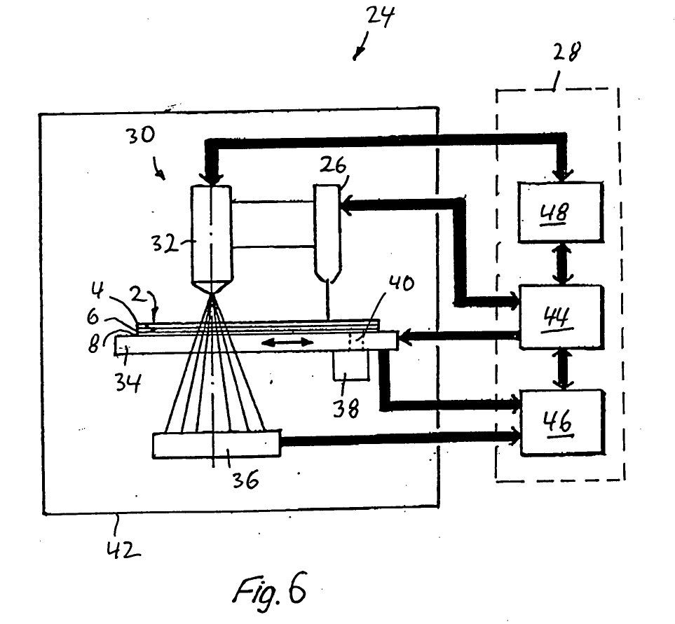

FIG. 6 illustrates an exemplary embodiment of a boring device 24 according to the invention for executing a method according to the invention for boring the via holes 22 for connecting the contact regions 16 and 28 of the layers 4, 6 and 8 of the printed circuit board 2. The boring device 24 includes boring device, which in this exemplary embodiment includes a laser 26, for boring the via holes 22. The type and manner of boring by use of laser radiation is known to the person having ordinary skill in the art per se and will therefore not be described in detail. The laser 26 is connected to control device 28 for generating control signals for controlling the laser 26 in accordance with the via holes 22 to be bored, the operation of this control being explained in detail below.

The boring device 24 according to the invention furthermore includes a device, integrated into the device 24, for determining a layer-to-layer misalignment, in this exemplary embodiment the device being formed by an X-ray measuring device, which in this exemplary embodiment is configured as an X-ray microscope and includes a microfocus X-ray tube 32. The X-ray tube 32 serves for X-raying the printed circuit board 2, which is provided on a carrier 34. An X-ray image detector 36, the output signal of which can be fed to the control device 28, is provided on the side of the carrier 34 opposite the X-ray tube 32. The X-ray tube 32 can be controlled by the control device 28. In this exemplary embodiment, the carrier 34 is connected to positioning device for positioning the carrier 34 and thereby the printed circuit board 2 relative to the laser 26 and the X-ray tube 32. The positioning device can be formed by a precision X-Y table, for example, by use of which the carrier 34 and thereby the printed circuit board 2 can be precisely positioned relative to the laser 26 and the X-ray tube 32 in a reproducible manner with high accuracy. The positioning device in this exemplary embodiment is configured in such a manner that the carrier 34 can be positioned in and out of the plane of the drawing and parallel to the plane of the drawing, namely in the X and Y directions.

For attaching the printed circuit board 2 to the carrier 34 in a manner free of positional changes relative to the position of the printed circuit board 2 when the layer-to-layer misalignment is determined, there is provided attaching device, which in this exemplary embodiment includes a vacuum suction device, which is indicated with the reference numeral 38 in FIG. 6 and sucks on the printed circuit board 2 through recesses 40 formed in the carrier 34 and thus attaches it to the carrier 34. The control device 28 can control the vacuum suction device in such a manner, for example, that the attaching of the printed circuit board 2 onto the carrier 34 is released only when all via holes 22 have been bored.

According to the invention, in this exemplary embodiment the boring device in the form of the laser 26 and the device for determining a layer-to-layer misalignment in the form of the X-ray tube 32 and the X-ray image detector 36 fit into a common housing 42, which shields the outside from the X-ray radiation generated by the X-ray tube 32 in its interior.

The operation of the boring device 24 according to the invention is as follows:

To bore via holes 22 in the printed circuit board 2, the printed circuit board is first placed on the carrier 34 and fixed to the carrier 34 by use of the vacuum suction device 38. Following this, a first control unit 44 of the control device 28 controls the positioning device in such a manner that the carrier 34, and thereby the printed circuit board 2, moves into a position relative to the X-ray tube 32 in which any layer-to-layer misalignment of the layers 4, 6 and 8 of the printed circuit board 2 relative to one another can be determined. The type and manner of determining the layer-to-layer misalignment is generally known per se to the person having ordinary skill in the art and will therefore not be explained in detail.

The X-ray images generated by the X-raying of the printed circuit board 2 with the X-ray tube 32 are received by the X-ray image detector 36 and fed to an evaluation unit 46 of the control device 28, which determines any layer-to-layer misalignment of the layers 4, 6 and 8 of the printed circuit board 2 to one another from the taken X-ray images. The control of the X-ray tube 32 is accomplished by a second control unit 48 of the control device 28. After evaluation of the X-ray images which were taken and determination of the layer-to-layer misalignment, it is first established, based for example on an evaluation of the expected remaining radial widths of the contact regions 16, 18 and 20 formed when forming the via holes 22, whether the printed circuit board 2 can be further processed.

If the printed circuit board 2 cannot be further processed and must accordingly be rejected, a corresponding signal is generated, on the basis of which a user can remove the printed circuit board 2 from the boring device 24.

If on the other hand the printed circuit board can be further processed, the first control unit 44 of the control device generates control signals to control the laser 26 in accordance with the via holes to be bored and control signals to control the positioning device. Thereupon the positioning device positions the carrier 34, and thereby the printed circuit board 2, relative to the laser 26 in such a manner that the laser 26 can bore the desired via holes.

In the illustrated embodiment, the printed circuit board 2 is fixed to the carrier 34 both during the determination of the layer-to-layer misalignment and also during the boring of the via holes, so that the via holes 22 can be formed with high accuracy, and inaccuracies that can be traced back to a positional change of the printed circuit board 2 relative to the carrier 34, are reliably prevented. By controlling the positioning device, the first control unit 44 of the control device 28 can control the position of the carrier 34 relative to the laser 26 with high accuracy and high reproducibility.

Given the fact that the determination of a layer-to-layer misalignment and the boring of the via holes occur in one and the same device, namely the boring device 24, the via holes 22 can be produced with high accuracy. In addition, the boring of via holes on the printed circuit board 2 is particularly time-saving and can thereby be performed efficiently. Setting-up times, which occur in devices as per the prior art in connection with removal of the printed circuit board 2 from a device to determine the layer-to-layer misalignment and placing the printed circuit board into a boring device, are completely eliminated. This reduces personnel costs.

While this invention has been described as having a preferred design, it is understood that it is capable of further modifications, and uses and/or adaptations of the invention and following in general the principle of the invention and including such departures from the present disclosure as come within the known or customary practice in the art to which the invention pertains, and as may be applied to the central features hereinbefore set forth, and fall within the scope of the invention or limits of the claims appended hereto.

1. A device, comprising:
a) device configured for boring via holes in a layer of a multilayer printed circuit board for connecting contact regions of at least a first layer of a multilayer printed circuit board to contact regions of at least a second layer of the multilayer printed circuit board, in use;
b) a control device configured for generating control signals for controlling the boring device in accordance with the via holes to be bored, in use;
c) a device configured for determining a layer-to-layer misalignment between the first layer and the second layer of the multilayer printed circuit board, in use, the determining device being connected to the control device and feeding a signal representing a determined layer-to-layer misalignment to the control device, in use, and the control device generates control signals as a function of the determined layer-to-layer misalignment in such a manner that the boring device bores the via holes as a function of the determined layer-to-layer misalignment, in use; and
d) the boring device including at least one laser, and the at least one laser being configured for forming the via holes in the multilayer printed circuit board, in use.

2. Device according to claim 1, wherein:
a) the boring device and the device for determining a layer-to-layer misalignment are fitted onto a common base.

3. Device according to claim 1, wherein:
a) a carrier is provided for the printed circuit board, the carrier being configured for holding the printed circuit board during the boring of the via holes, in use, and the carrier holds the printed circuit board during the boring of the via holes substantially free of positional change relative to the position of the printed circuit board during the determination of the layer-to-layer misalignment.

4. Device according to claim 1, wherein:
a) a carrier is provided, the carrier being configured for holding the printed circuit board, and the attaching device being configured to fix the printed circuit board to the carrier substantially free of positional change, in use, during at least one of:
i) the determination of a layer-to-layer misalignment; and
ii) during the boring of the via holes.

5. Device according to claim 4, wherein:
a) the carrier is configured in such a manner that the printed circuit board can be released for removal from the device only after the boring of the via holes.

6. Device according to claim 4, wherein:
a) a positioning device is provided for positioning the printed circuit board relative to one of the boring device and the device for determining the layer-to-layer misalignment, in use.

7. Device according to claim 6, wherein:
a) the positioning device can position the printed circuit board relative to at least one of the boring device and the device for determining the layer-to-layer misalignment at least in a plane parallel to the printed circuit board, in use.

8. Device according to claim 1, wherein:
a) the device for determining a layer-to-layer misalignment determines the layer-to-layer misalignment by use of an imaging method.

9. Device according claim 1, wherein:
a) the device for determining the layer-to-layer misalignment includes at least one X-ray measuring device for measuring the layer-to-layer misalignment.

10. Device according to claim 9, wherein:
a) the X-ray measuring device includes at least one microfocus X-ray tube.

11. Device according to claim 1, wherein:
a) the control device is programmed in such a manner that the control of the boring device, in use, is exercised only when the determined layer-to-layer misalignment between the first layer and the second layer of the multilayer printed circuit board falls below a predefined value.

12. Device according to claim 1, wherein:
a) the device for determining a layer-to-layer misalignment determines the layer-to-layer misalignment on the basis of the contact regions of the layers of the printed circuit board, in use.

13. Device according to claim 1, wherein:
a) the device for determining a layer-to-layer misalignment determines a layer-to-layer misalignment on the basis of markings provided on the layers of the printed circuit board.

14. Method for boring via holes for connecting contact regions of at least a first layer of a multilayer printed circuit board to contact regions of at least a second layer of the multilayer printed circuit board, comprising:
a) determining a layer-to-layer misalignment between the first layer and the second layer of the multilayer printed circuit board;
b) providing a control device, the control device generating control signals for controlling the boring device for boring the via holes, and the control device generates the control signals as a function of the determined layer-to-layer misalignment in such a manner that the via holes are produced as a function of the determined layer-to-layer misalignment;
c) holding the printed circuit board substantially free of positional changes relative to the carrier during the determination of the layer-to-layer misalignment and during the boring; and
d) boring the via holes are bored by use of laser radiation.

15. Method according to claim 14, wherein:
a) the layer-to-layer misalignment is determined by use of an imaging method.

16. Method according to claim 15, wherein:
a) the layer-to-layer misalignment is determined by use of an X-ray measuring device.

17. Method according to claim 16, wherein:
a) the X-ray measuring device includes at least one microfocus X-ray tube.
